(19) United States
(12) Patent Application Publication
(10) Pub. No.: US 2007/0278642 A1
(43) Pub. Date: Dec. 6, 2007

(54) SEMICONDUCTOR DEVICE

(75) Inventors: Hiroyuki Yamaguchi, Nagano (JP); Kazuya Oota, Kanagawa (JP); Atsuhiro Harada, Gifu (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Sony Corporation, Tokyo (JP)

(21) Appl. No.: 11/753,119

(22) Filed: May 24, 2007

(30) Foreign Application Priority Data
May 31, 2006 (JP) 2006-152424

(51) Int. Cl. H01L 23/02

(52) U.S. Cl. 257/686

(57) ABSTRACT

A semiconductor device includes a first semiconductor module having a semiconductor part on a board and conductive parts for making connection with another board on an upper surface of the board, a second semiconductor module having a semiconductor part on a board and conductive parts for making connection with another board on a lower surface of the board, and a plurality of relay boards placed between conductive parts formed on an upper surface of the first semiconductor module and the conductive parts formed on a lower surface of the second semiconductor module for connecting both surfaces' conductive parts, a side length of the relay board corresponding to one of a plurality of divided portions of a side of the first semiconductor module's board, the relay board having a plurality of conductive via formed on an upper and lower surface of the relay board allowing electric conduction between both surfaces.

### BACKGROUND OF THE INVENTION

1. Field of the Invention

The present invention relates to a semiconductor device configured by overlaying semiconductor modules formed by mounting semiconductor packages on boards.

2. Description of Prior Art

Typically, SIP (System in package) whereby a plurality of semiconductor chips with various different functions are overlaid each other to be placed in a single package is widely known as a technology for increasing integration degrees of IC (Integrated Circuit) In recent years, attentions are focused on PoP (Package on Package) method whereby packages are overlaid each other. As methods for electrically connecting among overlaid packages, a connection method employing solder balls as shown in FIG. 19, or a connection method employing a cavity board having conductive via as shown in FIG. 20, and so forth are known. In both FIG. 19 and FIG. 20A indicates a perspective figure and FIG. 20B indicates a side figure.

FIG. 19A is a figure showing a state before a PoP part 10a configured as mounting a package 1 on a board 13a and a PoP part 10b configured as mounting a package 2 on a board 13b are connected, and a plurality of solder balls 14 are placed between the PoP parts. FIG. 20A is a figure showing a state before the PoP part 10a and the PoP part 10b are connected, and a cavity board 15 configured as its central portion is cut out to fit in the package 2 is placed between the PoP parts. An upper surface and a lower surface of the cavity board 15 are electrically conducted by formation of conductive via and so forth. FIG. 20B is a figure showing a state where the PoP part 10a and the PoP part 10b are connected by solder cream 18 with the cavity board 15 in between.

In Japanese Patent Application Publication No. 2000-312314, it is disclosed that a single cavity board having conductive via and configured to surround a package is placed between packages, and all of them are overlaid together by thermocompression.

### SUMMARY OF THE INVENTION

However, when PoP parts mounting tall type packages are electrically connected each other by employing solder balls, it is necessary to leave height between the PoP parts to be overlaid, and to secure the height, diameters of solder balls for connecting between the PoP parts need to be wide. FIG. 21 shows a relationship between diameters of solder balls and a space between the overlaid PoP parts. If it is necessary to secure 0.2 mm height space for between PoP parts, solder balls with 0.275 mm diameters may be used, as shown in FIG. 21A. Similarly, if it is necessary to secure 0.3 mm height between PoP parts, solder balls with 0.35 mm diameter as shown in FIG. 21B need to be used, and if it is necessary to secure 0.4 mm height, solder balls with 0.45 mm diameter need to be used.

When diameters of solder balls are arranged to be large, a pitch between solder balls also need to be wide, that is, a pitch between solder balls increase in accordance with diameters of solder balls. For example, while a pitch in FIG. 21A is 0.5 mm, a pitch in FIG. 21B is 0.65 mm, and a pitch in FIG. 21C is 0.8 mm. In other words, there is an issue that space itself of a PoP part's board need to be wide when large solder balls are used. FIG. 22 shows examples where board space of a PoP part increases or decreases in accordance with different pitches between solder balls. Same numbers of connecting terminals (120 pins) are used in both FIG. 22A and FIG. 22B for PoP parts. While a side of a PoP part in FIG. 22A is 11.5 mm due to a 0.5 mm pitch between terminals, a side of a PoP part in FIG. 22B needs to be 14 mm due to a wide pitch (0.8 mm) between terminals, and thereby a PoP part becomes large.

Furthermore, when a method whereby a cavity board having conductive via and configured to surround a package is overlaid between PoP parts for connecting both PoP parts is employed, warpage or torsion tends to be caused to a cavity board due to its shape characteristics. If warpage or torsion is caused to a cavity board for joining PoP parts, it would lead to disconnection or decreased mounting reliability of a overlaid PoP device.

FIG. 23A and FIG. 23B show configuration examples where PoP parts are overlaid with a cavity board in between. FIG. 23A is a perspective figure showing a state before PoP parts are connected, and FIG. 23B is a side figure showing a state after the PoP parts are connected. FIG. 23 shows a state where warpage or torsion is caused on the cavity board 15 for connecting the PoP part 10a and the PoP part 10b. When this kind of cavity board 15 is used, it is necessary to connect portions other than electrically connected portions by joining materials and so forth to avoid disconnection. However, there is an issue that reworking would be difficult, if connection is made by joining materials and so forth. Also, PoP parts and a cavity board need to be overlaid all together to avoid disconnection caused by warpage or torsion, but in that case, there is an issue that yields of a overlaid PoP device as whole would be lowered, because respective handling for each package is not allowed even though detections are found at a single package.

Accordingly, it is desirable to achieve overlaying of a plurality of semiconductor modules with a simple configuration and to improve mounting reliability. The present invention is made in view of the above issues.

In an embodiment of the present invention, there is provided a semiconductor device including a first semiconductor module having a semiconductor part on a board, and a conductive part for making connection with another board on an upper surface of the board, a second semiconductor module having a semiconductor part on a board, and a conductive part for making connection with another board on a lower surface of the board, and a plurality of relay boards between the first semiconductor module and the second semiconductor module for electrically connecting both modules. Each side of the relay boards is configured to correspond to one of a plurality of divided portions of a side of the first semiconductor module's board. The relay boards having a plurality of conductive via on an upper surface and a lower surface for electrically conducting both surfaces are placed between a conductive part on an upper surface of the first semiconductor module and a conductive part on a lower surface of the second semiconductor module, and thereby both conductive parts are connected.

By this arrangement, a plurality of relay boards are arranged per one side of a semiconductor module's board, and therefore warpage or torsion may not easily caused for in relay boards.

According to the present invention, warpage or torsion may not easily occurred on relay boards for connecting between semiconductor modules, and connection states between semiconductor modules may be improved.

### BRIEF DESCRIPTION OF DRAWINGS

FIG. 1 is a perspective figure and a side figure for showing a lamination example of semiconductor modules according to an embodiment of the present invention;

FIG. 2 is a perspective figure for showing a configuration example of a semiconductor module according to an embodiment of the present invention;

FIG. 3 is a perspective figure for showing a configuration example of a semiconductor module according to an embodiment of the present invention;

FIG. 4 is a cross-sectional figure and a perspective figure for showing a configuration example of relay boards according to an embodiment of the present invention;

FIG. 5 is a perspective figure and a side figure for showing a configuration example of relay boards according to an embodiment of the present invention;

FIG. 6 is a side figure for showing an alignment example of a semiconductor module according to an embodiment of the present invention;

FIG. 7 is a side figure for showing an example where solder is supplied to semiconductor modules according to an embodiment of the present invention;

FIG. 8 is a side figure for showing an example where relay boards are mounted to semiconductor modules according to an embodiment of the present invention;

FIG. 9 is a perspective figure for showing an example where relay boards are mounted to a semiconductor module according to an embodiment of the present invention;

FIG. 10 is a side figure for showing an alignment example of semiconductor modules according to an embodiment of the present invention;

FIG. 11 is a side figure for showing an example where solder is supplied to semiconductor modules according to an embodiment of the present invention;

FIG. 12 is a side figure for showing lamination examples of semiconductor modules according to an embodiment of the present invention;

FIG. 13 is a side figure and a perspective figure for showing lamination examples of semiconductor modules according to an embodiment of the present invention;

FIG. 14 is a side figure for showing an example where connection is made by a relay board according to an embodiment of the present invention;

FIG. 15 is a side figure for showing a lamination example of semiconductor modules according to an embodiment of the present invention;

FIG. 16 is a perspective figure and a side figure for showing a lamination example of semiconductor modules according to a variant version of an embodiment of the present invention;

FIG. 17 is a perspective figure and a side figure for showing a lamination example of semiconductor modules according to a variant version of an embodiment of the present invention;

FIG. 18 is a side figure for showing an example where a heat sink is mounted to semiconductor modules according to a variant version of an embodiment of the present invention;

FIG. 19 is a perspective figure and a side figure for showing an example where connection is made by solder balls according to a method of related art;

FIG. 20 is a perspective figure and a side figure for showing an example where connection is made by a cavity board according to a method of related art;

FIG. 21 is an illustrative figure showing an example where connection is made by solder balls according to a method of related art;

FIG. 22 is an illustrative figure for showing a configuration example of a semiconductor module of related art; and

FIG. 23 is a perspective figure and a side figure for showing a lamination example between semiconductor modules according to a method related art.

### DETAILED DESCRIPTION OF EMBODIMENTS

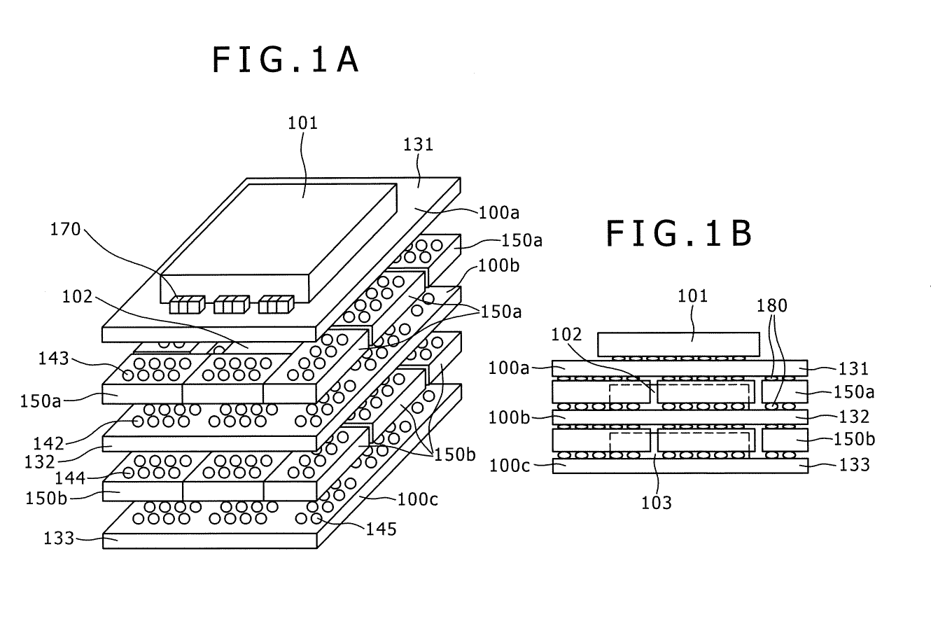

An embodiment of the present invention is explained below by referring to FIG. 1 to FIG. 18. The present embodiment is applied to a semiconductor device configured by overlaying PoP parts formed by mounting a package as a semiconductor part on a board with a plurality of relay boards in between.

FIG. 1A is a perspective figure showing configuration of the semiconductor device in the embodiment with a state before three PoP parts 100a to 100c are connected. FIG. 1B is a side figure showing a state after the PoP parts are connected. In the present embodiment, first to third PoP parts 100a to 100c are overlaid with a plurality of relay boards 150 in between. The first PoP part 100a is a semiconductor module having a package 101 and a plurality of passive parts 170, such as a resistor or a condenser on a board 131, and lands as conductive parts (not shown in the figure) are provided on a lower surface of the board 131. The second PoP part 100b is a semiconductor module having a package 102 on a board 132, and in addition to a plurality of lands 142 on an upper surface of the board 132, other lands (not shown in a figure) are provided on a lower surface. The third PoP part 100c is a semiconductor module having a package 103 on a board 133, and a plurality of lands 145 are provided on an upper surface of the board 133. Each package, 101, 102, and 103 is a semiconductor part having IC parts inside. Each PoP part 100a to 100c and the relay boards 150 are connected with solder cream 180, as shown in FIG. 1B.

An upper surface and a lower surface of relay boards 150a and 150b provided between each PoP part are electrically conducted by formation of conductive via and so forth. On upper surfaces of the relay boards 150a and b, lands 143 corresponding to lands provided on a lower surface of the first PoP part 100a are provided, and on lower surfaces, lands (not shown in the figure) are provided. On upper surfaces of the relay board 150b, lands 144 corresponding to lands provided on a lower surface of the second PoP part 100b are provided, and lands (not shown in the figure) are also provided on lower surfaces. As shown in FIG. 1A, it is configured as a plurality of relay boards 150 are arranged per one side of a PoP part to connect between each PoP part.

FIG. 1B shows a state where PoP parts 100a to 100c are connected, and each PoP part 100a to 100c and the relay boards 150 are connected by solder cream 180.

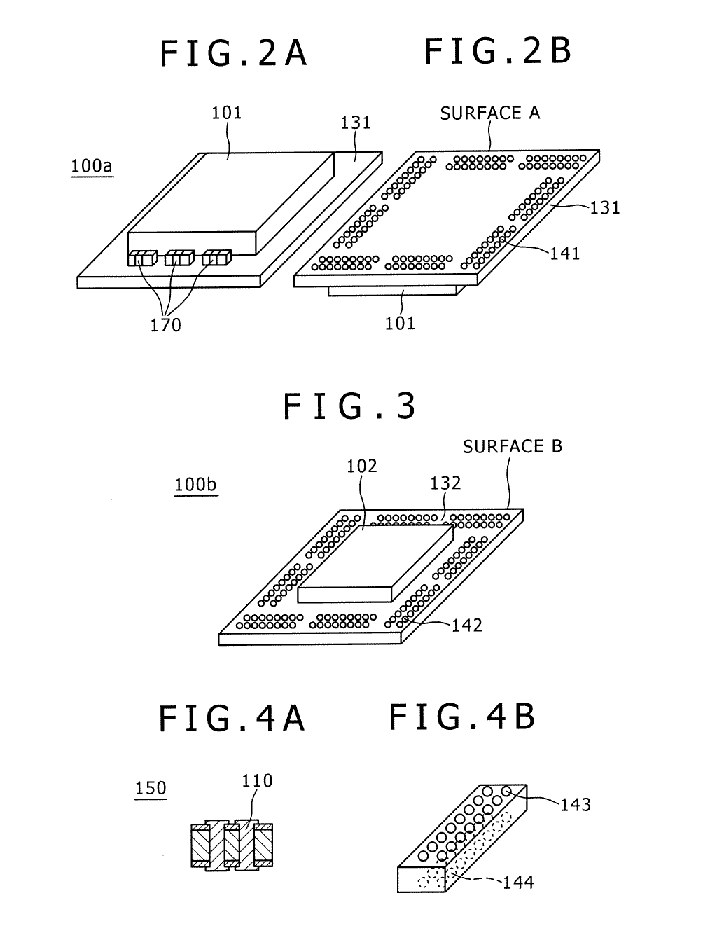

Configuration examples of the PoP parts 100a and 100b are explained by referring to FIG. 2 and FIG. 3. FIG. 2 is a figure showing a configuration example of the first PoP part 100a. The first PoP part 100a is configured by mounting, the package 101 and a plurality of passive parts 170 on, for example, the 12.0 mm square board 131. FIG. 2A shows an upper surface of the PoP part 100a, and FIG. 2B shows a lower surface. As shown in FIG. 2B, a plurality of lands 141 are formed on a lower surface (surface A) of the first PoP part 100a. Diameter of each land 141 is, for example, 0.45 mm and arranged per 0.8 mm pitch.

FIG. 3 is a figure showing a configuration example of the second PoP part 100b. The second PoP part 100b is configured by mounting the package 102 on, for example, the 12.0 mm square board 132. A size of the package 102 is, for example, 8.0 mm in length, 8.0 mm in width, and 0.5 mm (maximum value 0.6 mm) in height. A plurality of land 142 are formed on an upper surface (surface B) of the board 132, and each land 142 is arranged corresponding to the lands 141 provided on a lower surface (surface A) of the first PoP part 100a.

FIG. 4 is a figure showing a configuration example of the relay boards 150. As shown in cross-sectional figure of FIG. 4 A, upper surfaces and lower surfaces of the relay boards 150 are electrically conducted by conductive via 110 and so forth. Further, a plurality of lands 143 are provided on upper surfaces, and a plurality of lands 144 are provided on lower surfaces respectively, as shown in FIG. 4B. The lands 143 are provided on positions corresponding to the lands 141 on a lower surface (surface A) of the first PoP part 100a, and the lands 144 are provided on positions corresponding to the lands 142 on an upper surface (surface B) of the second PoP part 100b. Sizes of the relay boards 150 are, for example, 5.0 mm in length, 1.5 mm in width, and 0.5 mm in height, and it is configured as a plurality of the relay boards are arranged per 12.0 mm side of the second PoP part 100b. Height of the relay boards 150 is calculated as: [(salient height of a package placed below relay boards when overlaid (maximum value)+clearance)−solder connection thickness×2]. In the present embodiment, salient height (maximum) of a package is 0.6 mm, and therefore, when clearance is 0.1 mm and solder connection thickness is 0.1 mm, height of the relay boards 150 is calculated as 0.5 mm.

It is noted that if sizes of relay boards are made small, more number of relay boards for mounting may be required in accordance with sizes of PoP parts, and thereby costs could be increased. Therefore, preferably, large size of relay boards may be employed. If sizes of relay boards are set large, warpage or torsion tends to be caused on relay boards, and therefore several sizes may be tested to determine appropriate size to enable good yield.

Organic base materials, such as FR-4 (flame-resistant glass fabric base epoxy resin overlaid sheets) or inorganic base materials, such as ceramics are used as base materials of the relay boards 150. However, for mounting reliability, it is preferable to use base materials whose linear expansion coefficient is similar with that of base materials of PoP parts to be connected.

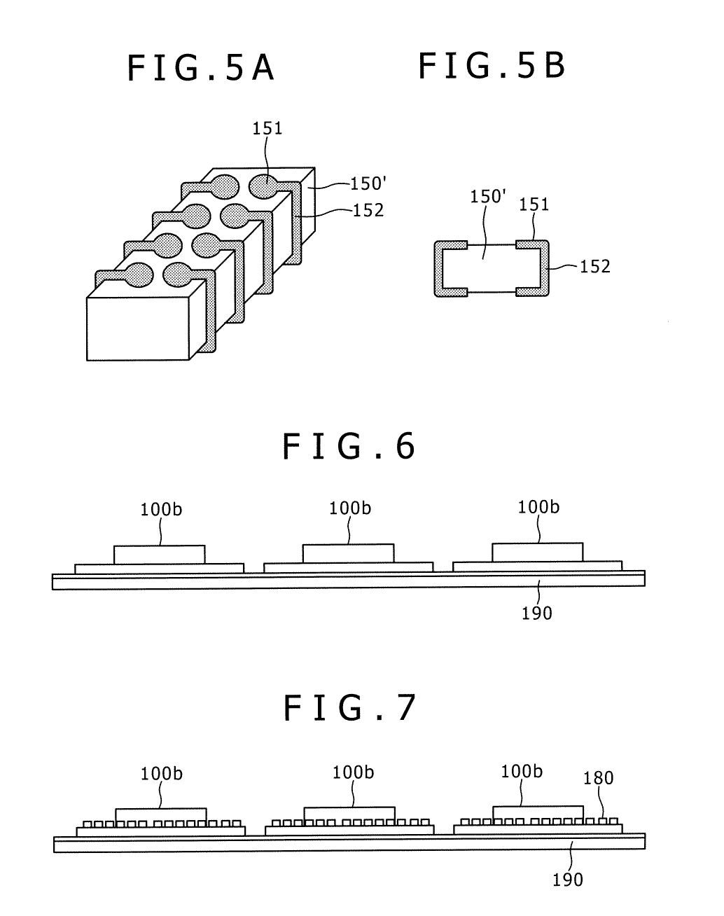

Further, although a configuration example of relay boards 150 where upper surfaces and lower surfaces are electrically conducted by formation of conductive via is explained in FIG. 4, as illustrated in a perspective figure of FIG. 5A and a side figure of FIG. 5B, relay boards 150′ where upper surfaces and lower surfaces are designed to be electrically conducted by edge plating 151 and wirings 152 may be employed.

Further, as lands of the relay boards 150, in addition to half ball type and full ball type of BGA (Ball Grid Array) types, LGA (Land Grid Array) types without balls may be employed.

Examples of fabrication processes of a semiconductor device according to a configuration of the present embodiment would be explained next by referring to FIG. 6 to FIG. 13.

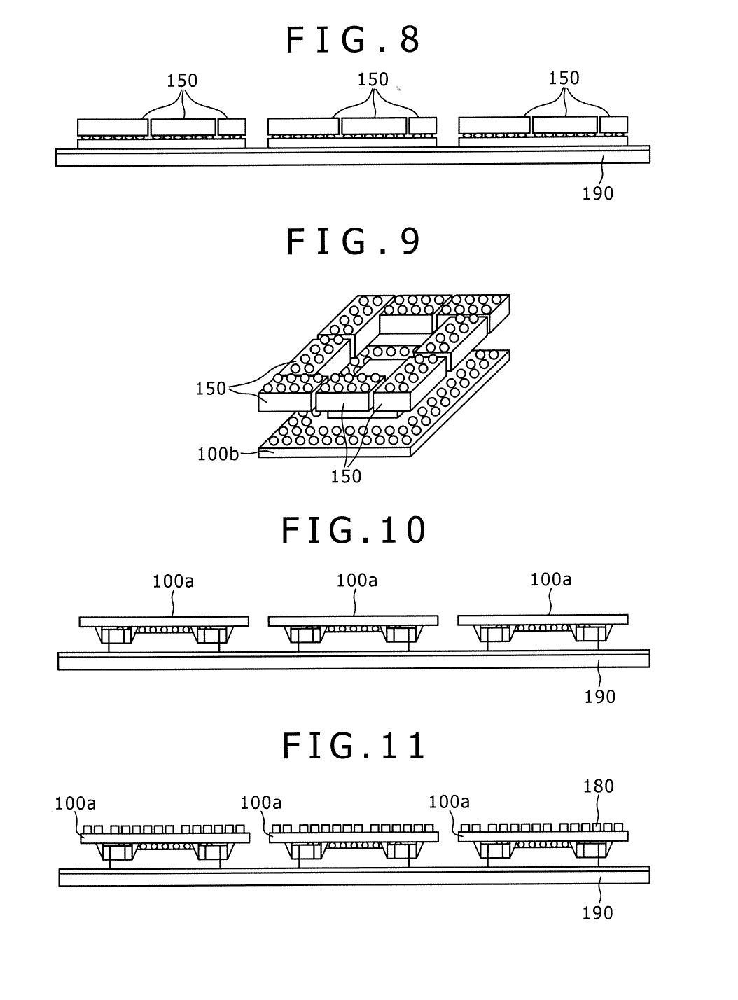

When the first PoP part 100a and the second PoP part 100b are overlaid, first, as shown in FIG. 6, the second PoP part 100b is arranged on a fixing board 190 whereon easy detachable adhesive is applied, and thereafter, the solder cream 180 is applied on the second PoP part 100b, as shown in FIG. 7. The plurality of relay boards 150 are provided on the applied solder cream 180, as shown in FIG. 8, and solder is hardened by reflow heating. It is configured as a plurality of the relay boards 150 are arranged per a side of the second PoP parts 100b, as shown in FIG. 9.

The first PoP part 100a having lands on a lower surface are arranged on the fixing board 190 by reversing an upper surface and a lower surface, as shown in FIG. 10. Next, as shown in FIG. 11, the solder cream 180 is applied on a lower surface of the first PoP part 100a.

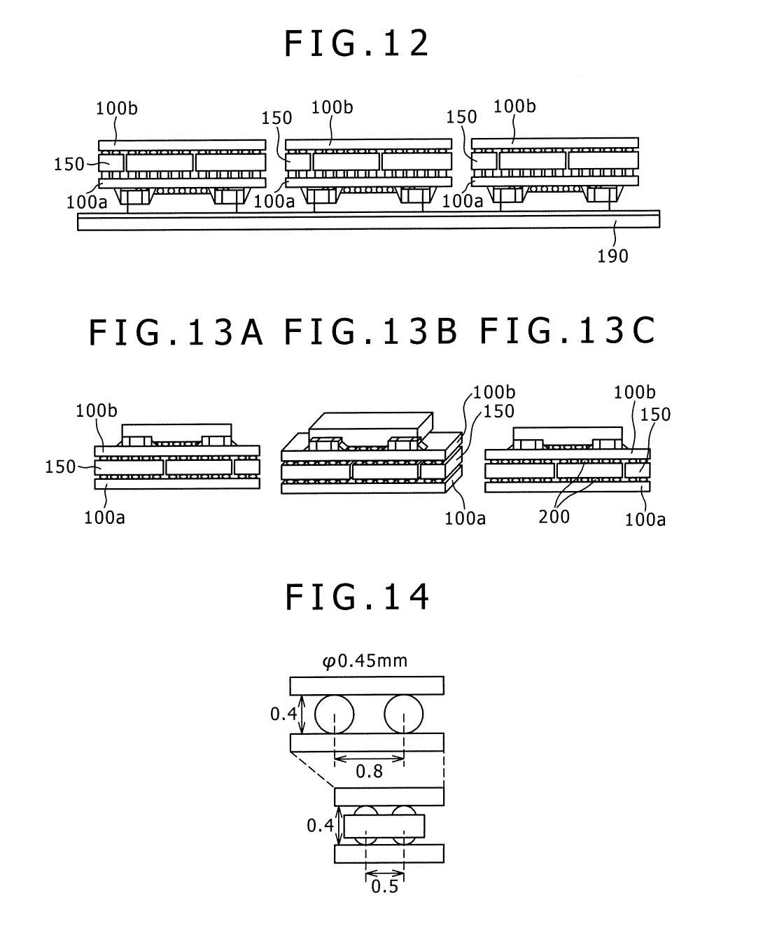

FIG. 12 shows a state where the second PoP part 100b mounting the relay boards 150 are overlaid on the first PoP part 100a. The second PoP part 100b is placed on the first PoP part 100a by reversing an upper surface and a lower surface, and solder is hardened by reflow heating in FIG. 12. FIG. 13 shows a state where the overlaid first PoP part 100a and the second PoP part 100b with the relay boards 150 in between are detached from the fixing board 190, and this is a complete form of a semiconductor device. FIG. 13A is a side figure, and FIG. 13B is a perspective figure.

It is noted that resin for reinforcement 200, such as underfill agent may be injected between a layer of the first PoP part 100a and a layer of the second PoP part 100b after operation check of PoP parts to improve physical reliability, as shown in FIG. 13C.

As the above, it is configured as lamination between each PoP part is performed by using a plurality of relay boards divided into an appropriate size, therefore, warpage or torsion is not easily caused to the relay boards comparing with a case where relay boards whose side length is equal to a side length of the PoP parts are used. Thereby, disconnection between PoP parts or decrease of mounting reliability of a semiconductor device as whole may be prevented.

In this case, mounting reliability of a semiconductor device is maintained even though all layers are not overlaid together, therefore, even though defects are found on partial packages, respective handling becomes possible to improve yield of a semiconductor device as whole.

Further, when a cavity board is formed by cutting out a central portion of a board according to a method of related art, the cut out central portion has to be thrown away, and unreusable. However, in case of formation of relay boards, no portions are thrown away, and therefore, costs may be reduced comparing with a case where a cavity board is employed.

Furthermore, by employing relay boards instead of solder balls as members for connecting between PoP parts, a connection pad pitch may be narrowed, and PoP parts may be miniaturized. For example, when connection is made with solder balls under a condition where 0.4 mm height for a space between PoP parts needs to be secured, a 0.8 mm pitch between solder balls is required, as shown in FIG. 14A. However, if connection is made with relay boards, a pitch of connecting terminals may be narrowed down to 0.5 mm, as shown in FIG. 14B, and thereby downsizing of a board itself becomes possible.

Further, rework becomes possible, because connection between PoP parts is made by solder.

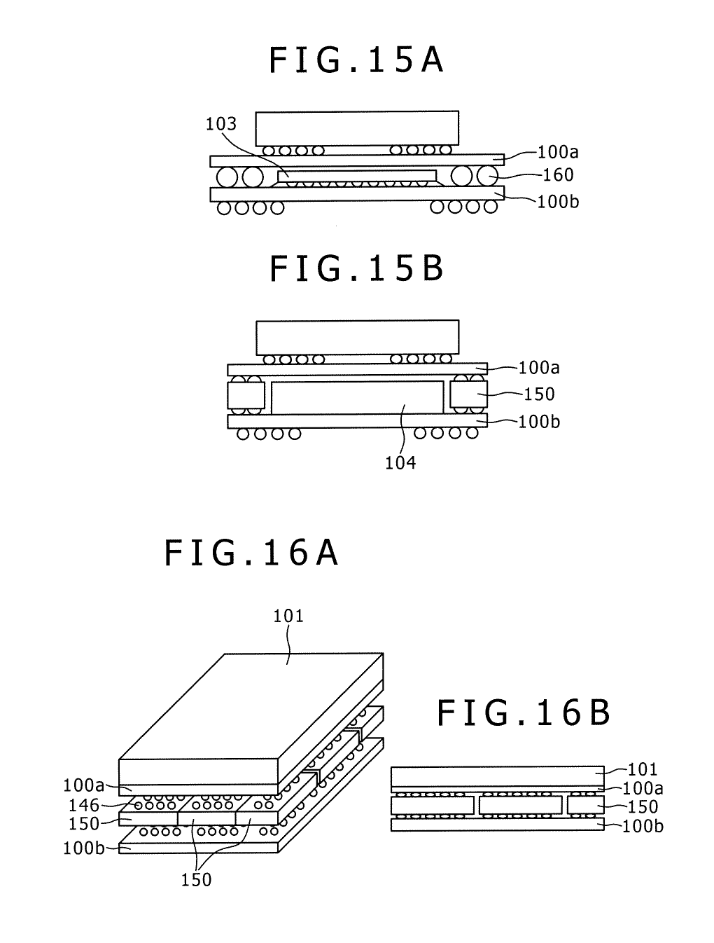

Furthermore, since relay boards are used for connection between layers, larger height space between PoP parts may be secured, comparing with a case where connection is made with solder balls. For this reason, tall type packages may be used as PoP parts. FIG. 15A is a side figure showing a state where connection is made between the first PoP part 100a and the second PoP part 100b with solder balls 160 in between. If connection is made with solder balls, enough height space may not be freed up between PoP parts, and therefore, a usable package is limited only to the short type package 103, such as a package connected by flip-chip, as illustrated in FIG. 15A. Compared with this, FIG. 15B is a side figure showing a configuration example of a case where relay boards are used for a connection between layers. FIG. 15B shows a state where the first PoP part 100a and the second PoP part 100b are connected with relay boards 150 in between, and according to this configuration, lamination of a tall type package 104, such as a package connected by wire bonding or MCP (Multi Chip Package) becomes possible.

Further, by adjusting a pitch of conductive via or edge plating provided to relay boards, larger numbers of connection lands may be secured.

Furthermore, by adopting many variations of terminal pitches, thickness (height), or pin numbers, and so forth for relay boards, and by standardizing each variation, it becomes possible to use relay boards for multipurpose.

It is noted that sizes of PoP parts are specified at the above explained embodiments for a purpose to provide a clear description, but sizes of PoP parts are not limited to the above mentioned sizes.

Further, in the above mentioned embodiment, lands of relay boards are configured as corresponding to lands of a PoP part, but as illustrated in FIG. 16, the first PoP part 100a and the second PoP part 100b having lands corresponding to lands 146 of relay boards 150 may be employed. In this case, lands of the first PoP part 100a are corresponded to lands 146 of relay boards 150, and therefore, a size of the board 131 of the first PoP part 10a is also narrowed down to a size equal to that of the package 101 mounted on the PoP part 100a. FIG. 16A is a perspective figure showing a state before the first PoP part 100a and the second PoP part 100b are connected, and FIG. 16B is a perspective figure showing a state after connection is made.

In the above embodiment, a square PoP part with same length and width has been cited for explanation so far. Alternatively, a rectangular PoP part may also be employable.

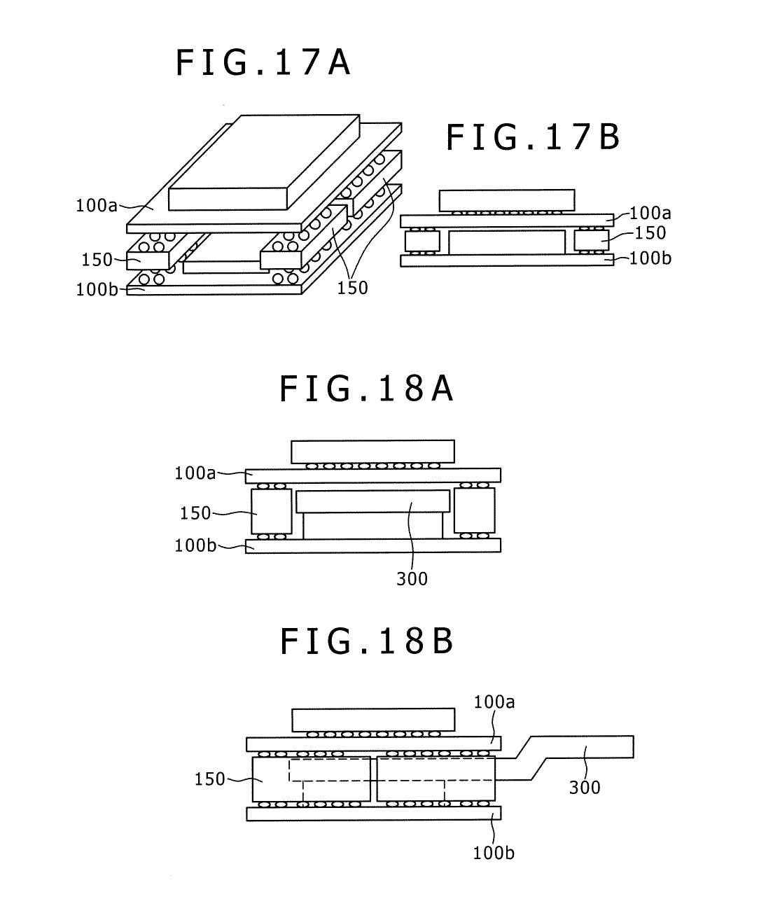

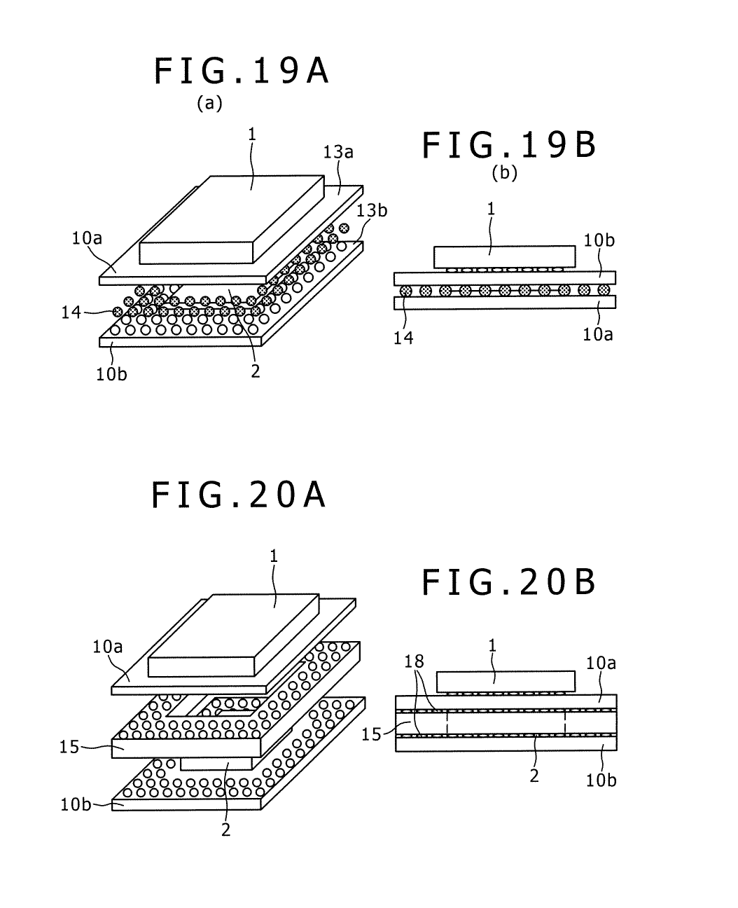

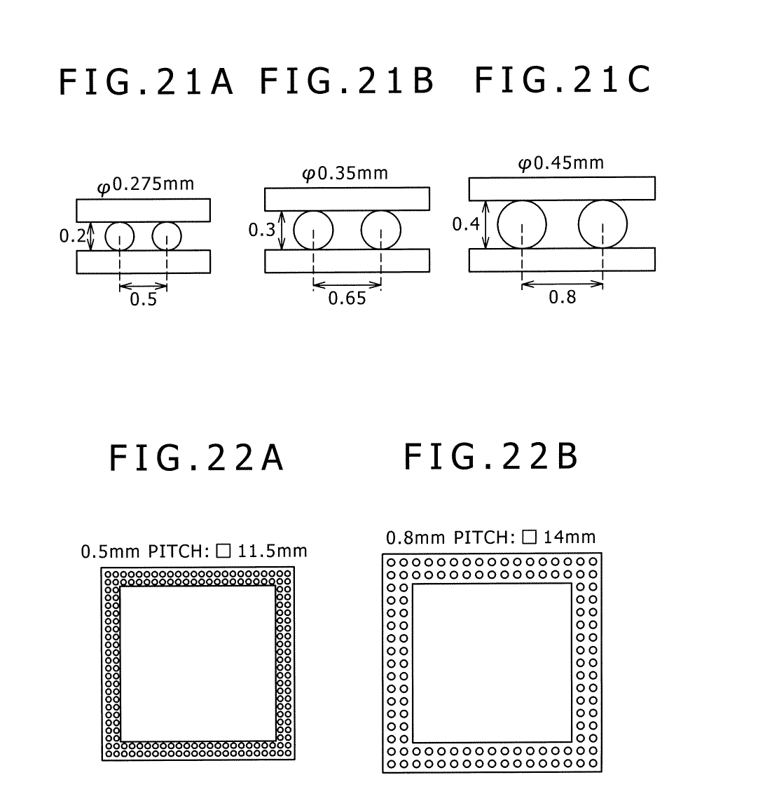

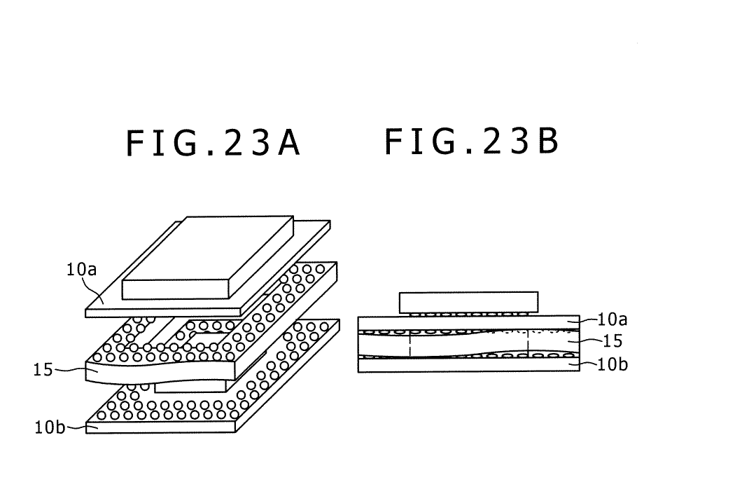

Further, in the above explained embodiment, it is configured as relay boards are arranged per each side of a PoP part, but as illustrated in FIG. 17, relay boards may be mounted for only two sides of a PoP part. FIG. 17A is a perspective figure showing a state before the first PoP part 100a and the second PoP part 100b are connected, and a plurality of relay boards 150 are arranged for two sides of the both parts. FIG. 17B is a side figure showing a state after connection is made. However, when relay boards 150 are arranged for only two sides of a PoP part, it is preferable to make symmetrical arrangement for both sides to avoid decrease of mounting reliability.

In this case, it may be configured as a heat sink for heat dissipation 300, and so forth are arranged between the first PoP part 100a and the second PoP part 100b to cool semiconductor chips by adjusting heights of relay boards and securing enough width between PoP parts, as illustrated in side figures of FIG. 18A and FIG. 18B.

The present application contains subject matters related to Japanese Patent Application No. 2006-152424 filed in Japanese Patent Office on May 31, 2006, the entire content of which being incorporated herein by reference.

It should be understood by those skilled in the art that various modifications, combinations, sub-combinations, and alterations may occur depending on design requirements and other factors insofar as they are within the scope of appended claims and equivalents thereof.

What is claimed is:

1. A semiconductor device comprising:
a first semiconductor module having a semiconductor part on a board and conductive parts for making connection with another board on an upper surface of the board;
a second semiconductor module having a semiconductor part on a board and conductive parts for making connection with another board on a lower surface of the board; and
a plurality of relay boards placed between conductive parts formed on an upper surface of the first semiconductor module and the conductive parts formed on a lower surface of the second semiconductor module for connecting both surfaces' conductive parts, a side length of the relay board corresponding to one of a plurality of divided portions of a side of the first semiconductor module's board, the relay board having a plurality of conductive via formed on an upper surface and a lower surface of the relay board for allowing electric conduction between both surfaces.

2. The semiconductor device according to claim 1, wherein
conductive parts for making connection with another board is further provide on an upper surface of the second semiconductor module, and
by employing the plurality of relay boards, a third semiconductor module is connected to the upper surface of the second semiconductor module's board.
